(19) United States
(12) Patent Application Publication
(10) Pub. No.: US 2016/0380124 A1
(43) Pub. Date: Dec. 29, 2016

(54) SURFACE PASSIVATION FOR SOLAR CELLS

(71) Applicants: Michael C. Johnson, Alameda, CA (US); Julien Penaud, Kraainem (BE); Jara Fernandez Martin, Paris (FR); Perine Jaffrennou, San Francisco, CA (US)

(72) Inventors: Michael C. Johnson, Alameda, CA (US); Julien Penaud, Kraainem (BE); Jara Fernandez Martin, Paris (FR); Perine Jaffrennou, San Francisco, CA (US)

(21) Appl. No.: 14/752,832

(22) Filed: Jun. 26, 2015

(51) Int. Cl. H01L 31/0216; H01L 31/18; H01L 31/028

(52) U.S. Cl. CPC H01L 31/02167; H01L 31/028; H01L 31/1864; H01L 31/1876; H01L 31/1868

(57) ABSTRACT

Methods of fabricating a solar cell, and resulting solar cell are described. In an example, the method for fabricating a solar cell include forming an oxide region over a light receiving region of a silicon substrate. The method can include forming an interfacial region over the light receiving surface of the silicon substrate. The method can also include forming a first surface region comprising aluminum oxide over the interfacial region and forming a second surface region over the first surface region. In some embodiments, the first surface region can have a thickness greater than the second surface region. In one embodiment, the second surface region can have a thickness greater than the thickness of the first surface region.

### BACKGROUND

Photovoltaic (PV) cells, commonly known as solar cells, are devices for conversion of solar radiation into electrical energy. Generally, solar radiation impinging on the surface of, and entering into, the substrate of a solar cell creates electron and hole pairs in the bulk of the substrate. The electron and hole pairs migrate to p-doped and n-doped regions in the substrate, thereby creating a voltage differential between the doped regions. The doped regions are connected to the conductive regions on the solar cell to direct an electrical current from the cell to an external circuit. When PV cells are combined in an array such as a PV module, the electrical energy collected from all of the PV cells can be combined in series and parallel arrangements to provide power with a certain voltage and current.

Efficiency is an important characteristic of a solar cell as it is directly related to the capability of the solar cell to generate power. Likewise, efficiency in producing solar cells is directly related to the cost effectiveness of such solar cells. Accordingly, techniques for increasing the efficiency of solar cells, or techniques for increasing the efficiency in the manufacture of solar cells, are generally desirable. Some embodiments of the present disclosure allow for increased solar cell manufacture efficiency by providing novel processes for fabricating solar cell structures. Some embodiments of the present disclosure allow for increased solar cell efficiency by providing novel solar cell structures.

### BRIEF DESCRIPTION OF THE DRAWINGS

FIG. 1 illustrates a flow chart representation of an example method for fabricating a solar cell, according to some embodiments.

FIGS. 2-5 cross-sectional views of example solar cells during the method for fabricating a solar cell of FIG. 1, according to some embodiments.

FIG. 6 illustrates an example solar cell, according to some embodiments.

FIG. 7 illustrates another example solar cell, according to some embodiments.

FIG. 8 illustrates a graph of saturation current for example solar cells.

FIG. 9 illustrates a graph of saturation current for example solar cells after exposure to ultraviolet light.

FIG. 10 illustrates a graph of reflectance versus wavelength for example solar cells.

FIG. 11 illustrates a graph of short circuit current for example solar cells.

FIG. 12 illustrates a graph of efficiency for example solar cells.

### DETAILED DESCRIPTION

The following detailed description is merely illustrative in nature and is not intended to limit the embodiments of the subject matter of the application or uses of such embodiments. As used herein, the word “exemplary” means “serving as an example, instance, or illustration.” Any implementation described herein as exemplary is not necessarily to be construed as preferred or advantageous over other implementations. Furthermore, there is no intention to be bound by any expressed or implied theory presented in the preceding technical field, background, brief summary or the following detailed description.

This specification includes references to “one embodiment” or “an embodiment.” The appearances of the phrases “in one embodiment” or “in an embodiment” do not necessarily refer to the same embodiment. Particular features, structures, or characteristics may be combined in any suitable manner consistent with this disclosure.

Terminology. The following paragraphs provide definitions and/or context for terms found in this disclosure (including the appended claims):

“Comprising.” This term is open-ended. As used in the appended claims, this term does not foreclose additional structure or steps.

“Configured To.” Various units or components may be described or claimed as “configured to” perform a task or tasks. In such contexts, “configured to” is used to connote structure by indicating that the units/components include structure that performs those task or tasks during operation. As such, the unit/component can be said to be configured to perform the task even when the specified unit/component is not currently operational (e.g., is not on/active). Reciting that a unit/circuit/component is “configured to” perform one or more tasks is expressly intended not to invoke 35 U.S.C. §112, sixth paragraph, for that unit/component.

“First,” “Second,” etc. As used herein, these terms are used as labels for nouns that they precede, and do not imply any type of ordering (e.g., spatial, temporal, logical, etc.). For example, reference to a “first” surface region of a solar cell does not necessarily imply that this surface region is the first surface region in a sequence; instead the term “first” is used to differentiate this surface region from another surface region (e.g., a “second” surface region of the solar cell). In an embodiment, a surface region can be an anti-reflective region, among others. In some embodiments, the surface region can be a barrier region, e.g., a region which protects a surface of a solar cell from moisture, and/or damage from ultra violet (UV) light.

“Based On.” As used herein, this term is used to describe one or more factors that affect a determination. This term does not foreclose additional factors that may affect a determination. That is, a determination may be solely based on those factors or based, at least in part, on those factors. Consider the phrase “determine A based on B.” While B may be a factor that affects the determination of A, such a phrase does not foreclose the determination of A from also being based on C. In other instances, A may be determined based solely on B.

“Coupled”—The following description refers to elements or nodes or features being “coupled” together. As used herein, unless expressly stated otherwise, “coupled” means that one element/node/feature is directly or indirectly joined to (or directly or indirectly communicates with) another element/node/feature, and not necessarily mechanically.

“Inhibit”—As used herein, inhibit is used to describe a reducing or minimizing effect. When a component or feature is described as inhibiting an action, motion, or condition it may completely prevent the result or outcome or future state completely. Additionally, “inhibit” can also refer to a reduction or lessening of the outcome, performance, and/or effect which might otherwise occur. Accordingly, when a component, element, or feature is referred to as inhibiting a result or state, it need not completely prevent or eliminate the result or state.

In addition, certain terminology may also be used in the following description for the purpose of reference only, and thus are not intended to be limiting. For example, terms such as “upper”, “lower”, “above”, and “below” refer to directions in the drawings to which reference is made. Terms such as “front”, “back”, “rear”, “side”, “outboard”, and “inboard” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

In the following description, numerous specific details are set forth, such as specific operations, in order to provide a thorough understanding of embodiments of the present disclosure. It will be apparent to one skilled in the art that embodiments of the present disclosure may be practiced without these specific details. In other instances, well-known techniques are not described in detail in order to not unnecessarily obscure embodiments of the present disclosure.

This specification includes a description of an example method for fabricating a solar cell, followed by example solar cells formed from the described methods. In various embodiments, the solar cell can be a single-crystalline solar cell or a multi-crystalline solar cell and can be a back-contact solar cell or a front-contact solar cell. Various examples are provided throughout.

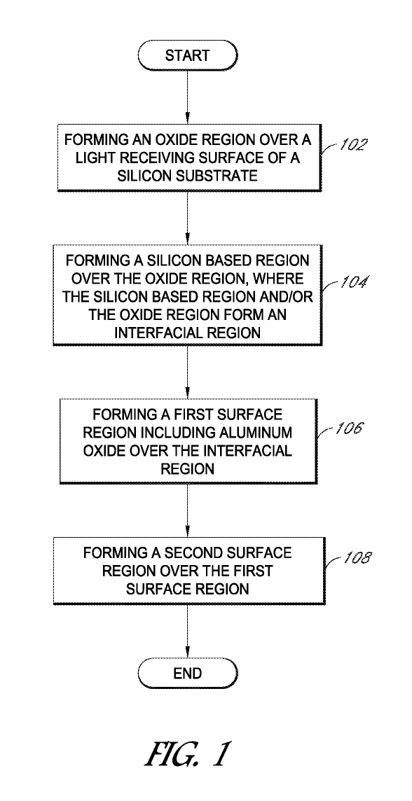

Turning now to FIG. 1, a method for fabricating a solar cell is shown, according to some embodiments. In various embodiments, the method of FIG. 1 can include additional (or fewer) blocks than illustrated. For example, in some embodiments, an oxide region, at block 102, need not be formed over a light receiving surface of a silicon substrate.

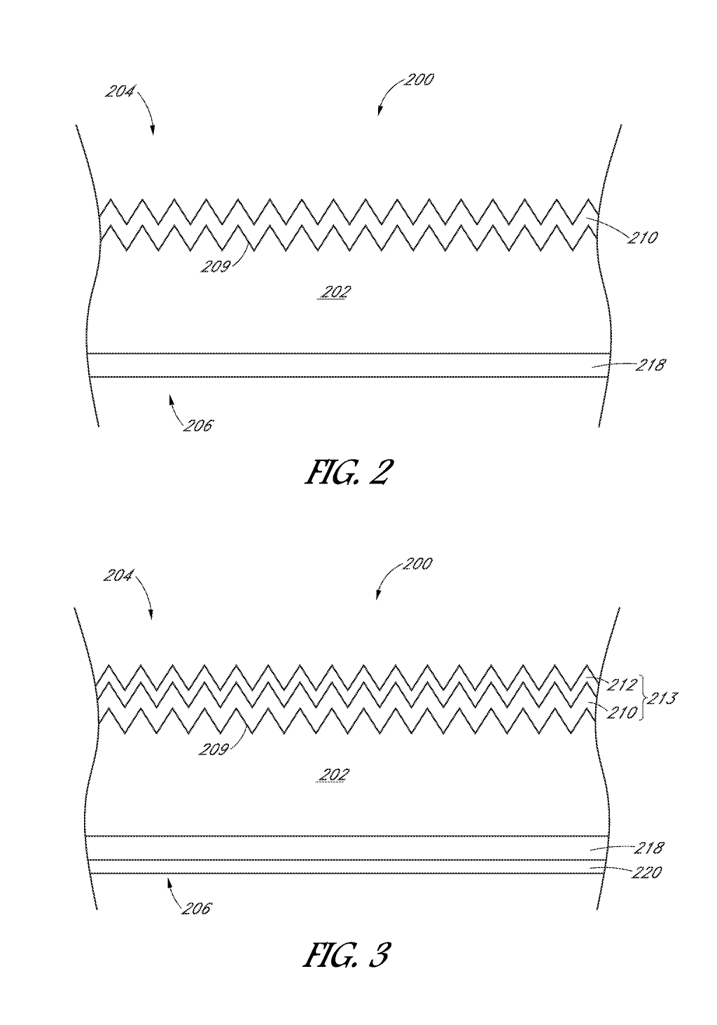

Referring to FIG. 2, and corresponding operation 102 of the flowchart of FIG. 1, an oxide region 210 can be formed over a light receiving surface 209 at the front side 204 of a silicon substrate 202, according to some embodiments. In an embodiment, the oxide region 210 can include silicon oxide, among others. In one embodiment, the oxide region can have a thickness in the range of 2-10 nm. In an embodiment, the oxide region can be thermally grown. In some embodiments, the oxide region 210 need not be formed.

In some embodiments, the silicon substrate 202 can be cleaned, polished, planarized and/or thinned or otherwise processed prior to the formation of the oxide region 210. In an embodiment, the silicon substrate 202 can be single-crystalline or a multi-crystalline silicon substrate. The silicon substrate 202 can be an N-type or a P-type silicon substrate. In an embodiment, the silicon substrate 202 can have a front side 204 opposite a back side 206.

In an embodiment, the light receiving region 209 at the front side 204 of the silicon substrate 202 can be textured as shown in FIG. 2. In an embodiment, a hydroxide-based wet etchant can be used to form at least a portion of the textured surface 202 and/or to texturize exposed portions of the substrate 202. A textured surface may be one which has a regular or an irregular shaped surface for scattering incoming light, decreasing the amount of light reflected off of the light-receiving and/or exposed surfaces of a solar cell 200. It is to be appreciated, however, that the texturizing of the back and/or front surfaces 206, 204 and even the textured surface 209 formation may be omitted from the process flow.

FIG. 3, and corresponding operation 104 of the flowchart of FIG. 1, illustrates forming a silicon based region 212 over the oxide region 210, according to some embodiments. In an embodiment, the silicon based region 212 can be an amorphous silicon, silicon nitride, or microcrystalline silicon, among others. In an embodiment, the silicon based region can be formed using a deposition process, chemical vapor deposition (CVD), or plasma enhanced chemical vapor deposition (PECVD), among other deposition processes. In an embodiment, the silicon based region 212 can have a thickness in the range of 1-20 nm.

In an embodiment, the silicon based region 212 and/or oxide region 210 can form an interfacial region 213. In an embodiment, the interfacial region 213 can have a thickness in the range of 1-30 nm. In an embodiment, the interfacial region 213 can include amorphous silicon, silicon nitride, microcrystalline silicon and/or silicon dioxide.

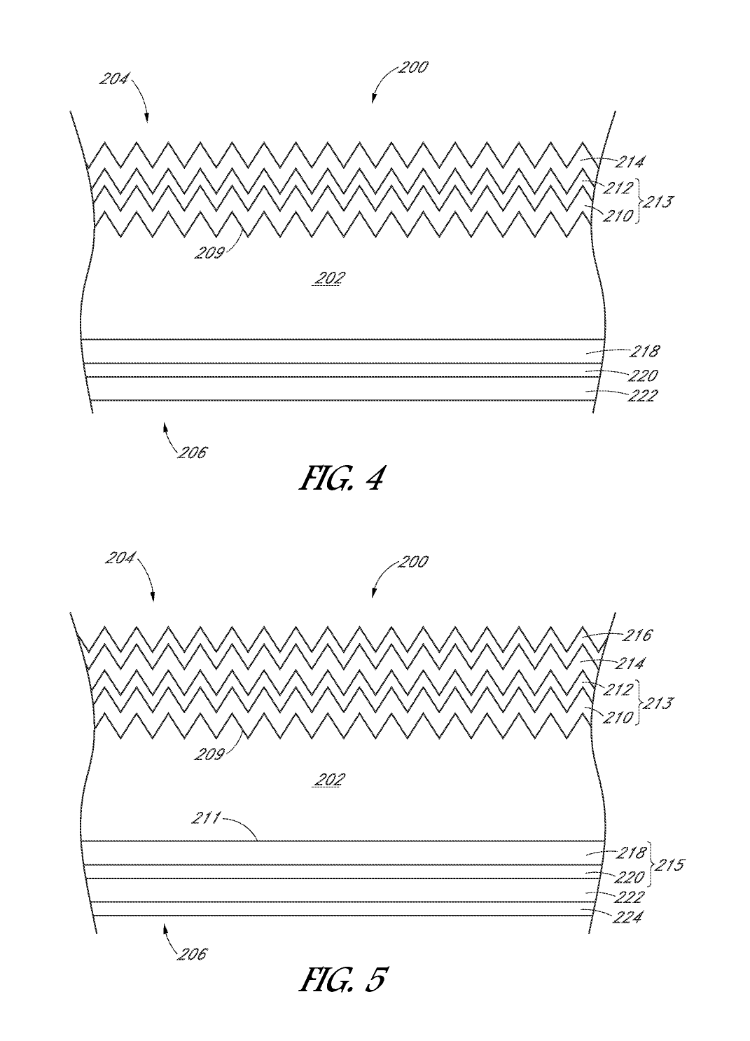

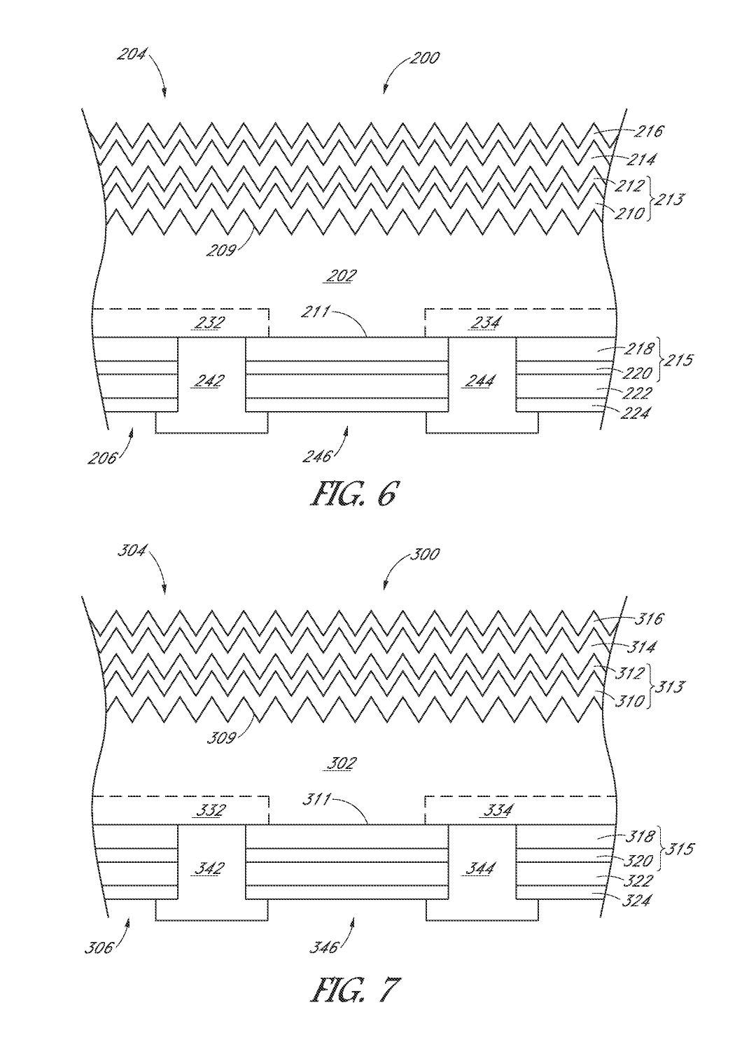

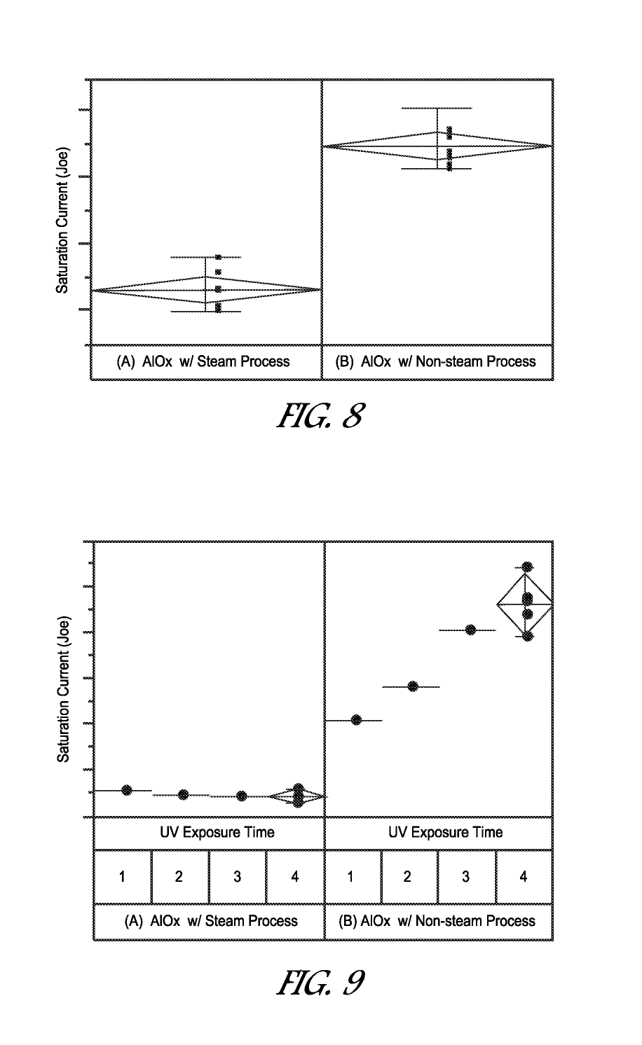

Referring to FIG. 4, and corresponding operation 106 of the flowchart of FIG. 1, a first surface region 214 can be formed over the interfacial region 213 at the front side 204 of the solar cell 200, according to some embodiments. In an embodiment, the first surface region 214 can include aluminum oxide. In one embodiment, the first surface region 214 can have a thickness in the range of 15-150 nm (e.g., as shown in FIG. 6). In an embodiment, the first surface region 214 can have an index of refraction (n) approximately in the range of 1.6-1.75. In some embodiments, the first surface region 214 can have a thickness in the range of 1-15 nm (e.g., as shown in FIG. 7). In one embodiment, the first surface region 216 can be an anti-reflective (AR) region. In some embodiments, the first surface region 214 can be substantially transparent.

In an embodiment, the first surface region 214 can be formed by performing atomic layer deposition (ALD), plasma enhanced atomic layer deposition (PEALD), spin on techniques, chemical vapor deposition (CVD), plasma enhanced chemical vapor deposition (PECVD), low-pressure chemical vapor deposition, molecular beam epitaxy (MBE), or sputtering, among other processes. In one embodiment, the first surface region 214 can be formed using a hydrogenated gas (e.g., during an ALD process). In some embodiments, the aluminum oxide of the first surface region 214 can be formed by depositing the aluminum oxide using steam precursors.

In an embodiment, using steam precursors to form the first surface region 214 having aluminum oxide can substantially improve the surface passivation at the light receiving surface 209 of the silicon substrate 202 (e.g., front surface saturation current Joe of less than 10 fA/cm2 can be achieved). In one embodiment, the first surface region 214 can be a hydrogen based passivation region. In an example, the first surface region 214 can include a hydrogenated aluminum oxide. In an embodiment, the first surface region 214 can include additional hydrogen (e.g., from the hydrogenated gas and/or steam precursor process) which can substantially reduce surface recombination at the light receiving surface 209 of the silicon substrate 202. In an embodiment, using steam precursors to form the first surface region 214 having aluminum oxide can substantially improve the reliability of the solar cell 200 to prolonged ultra violet (UV) light exposure (e.g., substantially reduce the surface recombination at the front side 202 of the solar cell 200 due to radiation exposure (Light induced degradation) from prolonged exposure to ultra violet (UV) light).

FIG. 5, and corresponding operation 108 of the flowchart of FIG. 1, illustrates forming a second surface region 216 over the first surface region 214, according to some embodiments. In an embodiment, the second surface region 216 can include silicon nitride, boron nitride or titanium nitride. In one embodiment, the second surface region 216 can have a thickness in the range of 1-10 nm (e.g., as shown in FIG. 6). In some embodiments, the second surface region 214 can have a thickness in the range of 50-100 nm (e.g., as shown in FIG. 7).

In an embodiment, the second surface region 216 can be a barrier region. In an example, the second surface region 216 can inhibit moisture infiltration (e.g., be a moisture barrier). In some embodiments, the second surface region 216 can also be an anti-reflective (AR) region. In an embodiment, the second surface region 216 can be substantially transparent.

In an embodiment, subsequent to forming the second surface region 216 over the first surface region 214, an annealing process can be performed. In an embodiment, the annealing can further improve the passivation at the interfacial region 213, first surface region 214 and the second surface region 216 (e.g., the annealing can further reduce surface recombination at the front side 204 of the solar cell 200). In one embodiment, the annealing process can include annealing the silicon substrate at a temperature in the range of approximately 350-550 degrees Celsius.

Referring to FIGS. 2-5, another oxide region 218 and silicon based region 220 can be disposed on another light receiving surface 211 at the back side 206 of the solar cell 200, according to some embodiments. In an embodiment, the light receiving surface 211 can be textured. In some embodiments, the light receiving surface 211 can be textured in the same or similar process to that of the light receiving surface 209 on the front side 204 (e.g., by using hydroxide-based wet etchant). In an embodiment, the oxide region 218 on the back side 206 can include silicon oxide, among others. In an embodiment, the silicon based region 220 on the back side 206 can be an amorphous silicon, silicon nitride, or microcrystalline silicon, among others. In some embodiments, the oxide region and silicon based region 218, 220 can form an interfacial region 215 on the back side 206 of the solar cell 200. In an embodiment, the oxide regions 210, 218 and silicon based regions 212, 220 on the front and back sides 204, 206 can be formed in the same process (e.g., in the same thermal growth and/or chemical vapor deposition (CVD) process). In some embodiments, the oxide region 218 and silicon based region 220 on the back side 206 of the solar cell 200 need not be formed. In an embodiment, the technique for forming of the interfacial region 215 is substantially similar to the technique for forming of the interfacial region 213 except the interfacial region 215 is located on the back side 204 of the solar cell 200. Accordingly, the description of the interfacial region 213 applies equally to the interfacial region 215 and will not be repeated here.

With reference to FIGS. 2-5, a surface regions 222, 224 can be disposed on the interfacial region 215 on the back side 206 of the solar cell 200, according to some embodiments. In an embodiment, the surface region 222 can include aluminum oxide. In an embodiment, the surface region 224 can include silicon nitride, boron nitride or titanium nitride. In an embodiment, the surface regions 214, 216 on the front side 204 and the surface regions 222, 224 on the back side 206 can be formed in the same process (e.g., in the same deposition process). In some embodiments, the surface regions 222, 224 need not be formed. In an embodiment, the technique for forming of the surface regions 222, 224 are substantially similar to the technique for forming of the surface regions 214, 216 except the surface regions 222, 224 are located on the back side 204 of the solar cell 200. Accordingly, the description of the surface regions 214, 216 apply equally to surface regions 222, 224 and will not be repeated here.

FIG. 6 illustrates an example solar cell formed from the methods described in FIGS. 1-5, according to some embodiments. As shown, the solar cell 200 can have a front side 204 which faces the sun during normal operation and a back side 206 opposite the front side 204. In an embodiment, the solar cell 200 can include a silicon substrate 202.

In an embodiment, an oxide region 210 can be disposed on a light receiving surface 209 on the front side 204 of the solar cell 200. In an embodiment, the oxide region 210 can include silicon oxide, among others. In one embodiment, the oxide region can have a thickness in the range of 2-10 nm. In some embodiments, the oxide region 210 may not be present.

In an embodiment, a light receiving surface 209 on the front side 204 of the solar cell 200 can be a surface of the silicon substrate 202 which faces the sun during normal operation of the solar cell 200 (e.g., to collect light). In one embodiment, the light receiving surface 209 at the front side 204 of the silicon substrate 202 can be textured as shown. A textured surface may be one which has a regular or an irregular shaped surface for scattering incoming light, decreasing the amount of light reflected off of the light-receiving and/or exposed surfaces of a solar cell. In some embodiments, the light receiving region 209 need not be texturized.

In an embodiment, a silicon based region 212 can be disposed on the oxide region 210. In an embodiment, the silicon based region 212 can be an amorphous silicon, silicon nitride, or microcrystalline silicon. In an embodiment, the silicon based region 212 can have a thickness in the range of 1-20 nm.

In an embodiment, the silicon based region 212 and/or oxide region 210 can form an interfacial region 213. In an embodiment, the interfacial region 213 can have a thickness in the range of 1-30 nm. In an embodiment, the interfacial region 213 can insulate the silicon substrate 202 from a first surface region 214. In an example, the silicon substrate can be an N-type silicon substrate and the first surface region 214 can include aluminum oxide. In some instances, negative charges from the aluminum oxide can be detrimental to the surface passivation at the light receiving surface 209 of N-type silicon substrate 202 (e.g., increase surface recombination at the front side 202 of the solar cell 200). In an embodiment, an oxide region 210 of the interfacial region 213 can insulate negative charges from aluminum oxide.

In an embodiment, a first surface region 214 can be disposed on the interfacial region 213. In an embodiment, the first surface region 214 can be configured to improve the optical properties (e.g., light collection properties) of the solar cell 200. In an embodiment, the first surface region 214 can be an anti-reflective (AR) region. In an embodiment, the first surface region 214 can include aluminum oxide. In an example, aluminum oxide can be used as an anti-reflective coating. In an embodiment, the first surface region 214 can have an index of refraction (n) approximately in the range of 1.6-1.75. In an embodiment, the first surface region 214 including aluminum oxide can have a substantially improved reflectance in the infrared range (e.g., from approximately 700 nm to 1000 nm) in comparison to a solar cell having a surface region including silicon nitride. In one embodiment, the first surface region 214 can have a thickness in the range of 15-150 nm.

In an embodiment, the first surface region 214 having aluminum oxide can be formed using steam precursors to substantially improve the surface passivation at the light receiving surface 209 of the silicon substrate 202 (e.g., substantially reduce the surface recombination at the front side 202 of the solar cell 200). In one embodiment, the first surface region 214 can be a hydrogen based passivation region. In an example, the first surface region 214 can include a hydrogenated aluminum oxide. In an embodiment, the first surface region 214 can include additional hydrogen (e.g., from the hydrogenated gas and/or steam precursor process) which can substantially reduce surface recombination at the light receiving surface 209 at the front side 204 of the solar cell 200. In an embodiment, using steam precursors to form the first surface region 214 having aluminum oxide can substantially improve the reliability of the solar cell 200 to prolonged ultra violet (UV) light exposure (e.g., substantially reduce the surface recombination at the front side 204 of the solar cell 200 due to radiation exposure (Light induced degradation) from prolonged exposure to ultra violet (UV) light).

In an embodiment, a second surface region 216 can be disposed over the first surface region 214. In an embodiment, the second surface region 216 can be configured to improve the overall solar cell passivation (e.g., substantially reduce surface recombination at the front side 204 of the solar cell 200). In an example, the second surface region 216 can include silicon nitride to improve the solar cell 200 passivation. In an embodiment, the second surface region 216 can be include silicon nitride, boron nitride or titanium nitride. In an embodiment, the first surface region 214 can have a thickness greater than a thickness of the second surface region 216. In an embodiment, the second surface region 216 can have a thickness in the range of 1-10 nm.

In an embodiment, the second surface region 216 can be a barrier region. In an example, the second surface region 216 can inhibit moisture infiltration (e.g., be a moisture barrier). In some embodiments, the second surface region 216 can also be an anti-reflective (AR) region. In an embodiment, the second surface region 216 can be substantially transparent.

In an embodiment, the silicon substrate 202 can be cleaned, polished, planarized and/or thinned or otherwise processed prior to the formation of an oxide region 210 on the front side 204 of the solar cell 200. In an embodiment, the silicon substrate 202 can be single-crystalline or a multicrystalline silicon substrate. In an embodiment, the silicon substrate 202 can be an N-type or a P-type silicon substrate. In an embodiment, the N-type and P-type doped regions 232, 234 can be in the silicon substrate 202. In an embodiment, the N-type and P-type doped regions can be disposed on the substrate 202. In an example, the N-type and P-type doped regions 232, 234 can be doped polysilicon regions. In an embodiment, the doped polysilicon regions can be disposed on the silicon substrate 202. In one embodiment, a dielectric region (e.g., a tunnel oxide) can be disposed between the doped polysilicon regions and the silicon substrate 202.

In an embodiment, metal contact fingers 242, 244 can be disposed on the silicon substrate 202 to allow for pathways for electrical current conduction from the N-type and P-type doped regions 232, 234 to an external circuit. In an embodiment, a separation region 246 can be formed to separate metal contact fingers 242, 244 of different polarity (e.g., a positive and a negative contact finger 242, 244) from contacting. In some embodiments, the separation region 246 can include a trench region, where the trench region can be a partially etched region of the silicon substrate 202. In an example, the trench region can include a light receiving surface 211 on the back side 206 and/or, in some embodiments, the light receiving surface 211 can be texturized. In an embodiment, the metal contact fingers 242, 244 can instead be disposed on a front side 204 of a solar cell 200 (e.g., for a front-contact solar cell). In the same embodiment, the separation region 246 between metal contact fingers 242, 244 can be formed to allow for reduced shading, e.g., to maximize light collection, on a front surface of a front-contact solar cell.

In an embodiment, another oxide region 218 and silicon based region 220 can be disposed on the back side 206 of the silicon substrate 202, according to some embodiments. In an embodiment, the oxide region 218 on the back side 206 can include silicon oxide, among others. In an embodiment, the silicon based region 220 on the back side 206 can be an amorphous silicon, silicon nitride, or microcrystalline silicon, among others. In some embodiments, the oxide region and silicon based region 218, 220 can form an interfacial region 215 on the back side 206 of the solar cell 200. In an embodiment, the oxide regions 210, 218 and silicon based regions 212, 220 on the front and back sides 204, 206 can be formed in the same process (e.g., in the same thermal growth and/or deposition process). In some embodiments, the oxide region 218 and silicon based region 220 on the back side 206 of the solar cell 200 need not be formed. In an embodiment, the structure of the interfacial region 215 is substantially similar to the structure of the interfacial region 213 except the interfacial region 215 is located on the back side 204 of the solar cell 200.

In an embodiment, surface regions 222, 224 can be disposed on the interfacial region 215 on the back side 206 of the solar cell 200, according to some embodiments. In an embodiment, the surface region 222 can include aluminum oxide. In an embodiment, the surface region 324 can include silicon nitride, boron nitride or titanium nitride. In an embodiment, the surface regions 214, 216 on the front side 204 and the surface regions 222, 224 on the back side 206 can be formed in the same process (e.g., in the same deposition process). In some embodiments, the surface regions 222, 224 need not be formed. In an embodiment, the structure of the surface regions 222, 224 are substantially similar to the structure of the surface regions 214, 216 except the surface regions 222, 224 are located on the back side 204 of the solar cell 200.

With reference to FIG. 7, an example solar cell is shown, according to some embodiments. As shown, the solar cell of FIG. 7 has similar reference numbers to elements of FIG. 6, wherein like reference numbers refer to similar elements throughout the figures.

FIG. 7 illustrates an example solar cell formed from the methods described in FIGS. 1-5, according to some embodiments. As shown, the solar cell 300 can have a front side 304 which faces the sun during normal operation and a back side 306 opposite the front side 304. In an embodiment, the solar cell 300 can include a silicon substrate 302.

In an embodiment, an oxide region 310 can be disposed on a light receiving surface 309 on the front side 304 of the solar cell 300. In an embodiment, the oxide region 310 can include silicon oxide, among others. In one embodiment, the oxide region can have a thickness in the range of 2-10 nm. In some embodiments, the oxide region 210 need not be formed.

In an embodiment, a light receiving surface 309 on the front side 304 of the solar cell 300 can be a surface of the silicon substrate 302 which faces the sun during normal operation of the solar cell (e.g., to collect light). In one embodiment, the light receiving surface 309 at the front side 304 of the silicon substrate 302 can be textured as shown. A textured surface may be one which has a regular or an irregular shaped surface for scattering incoming light, decreasing the amount of light reflected off of the light-receiving and/or exposed surfaces of a solar cell. In some embodiments, the light receiving region 309 need not be texturized.

In an embodiment, a silicon based region 312 can be disposed on the oxide region 310. In an embodiment, the silicon based region 312 can be an amorphous silicon, silicon nitride, or microcrystalline silicon. In an embodiment, the silicon based region 312 can have a thickness in the range of 1-20 nm.

In an embodiment, the silicon based region 312 and/or oxide region 310 can form an interfacial region 313. In an embodiment, the interfacial region 313 can have a thickness in the range of 1-30 nm. In an embodiment, the interfacial region 310 can insulate the silicon substrate 302 from a first surface region 314. In an example, the silicon substrate can be an N-type silicon substrate and the first surface region 314 can include aluminum oxide. In an embodiment, an oxide region 310 of the interfacial region 313 can insulate negative charges from aluminum oxide.

In an embodiment, a first surface region 314 can be disposed on the interfacial region 313. In an embodiment, the first surface region 314 can be configured to improve the overall solar cell passivation (e.g., reduce surface recombination at the front side 304 of the solar cell 300). In an example, the first surface region 214 can include aluminum oxide to improve the solar cell 300 passivation. In one embodiment, the first surface region 314 can have a thickness in the range of 1-15 nm. In an embodiment, the first surface region 214 can have an index of refraction (n) approximately in the range of 1.6-1.75. In one embodiment, the first surface region 314 can be substantially transparent.

In an embodiment, the first surface region 314 having aluminum oxide can be formed using steam precursors to substantially improve the surface passivation at the light receiving surface 309 of the silicon substrate 302 (e.g., reduce the surface recombination at the front side 302 of the solar cell 300). In one embodiment, the first surface region 314 can be a hydrogen based passivation region. In an example, the first surface region 314 can include a hydrogenated aluminum oxide. In an embodiment, the first surface region 314 can include additional hydrogen (e.g., from the hydrogenated gas and/or steam precursor process) which can substantially reduce surface recombination at the light receiving surface 309 of the silicon substrate 302. In an embodiment, using steam precursors to form the first surface region 314 having aluminum oxide can substantially improve the reliability of the solar cell 300 to prolonged ultra violet (UV) light exposure (e.g., substantially reduce the surface recombination at the front side 302 of the solar cell 300 due to radiation exposure (Light induced degradation) from prolonged exposure to ultra violet (UV) light).

In an embodiment, a second surface region 316 can be disposed on the first surface region 314 at the front side 204 of the solar cell 200. In an embodiment, the second surface region 316 can be configured to substantially improve the optical properties (e.g., light collection properties) of the solar cell 300. In an embodiment, the second surface region 314 can be an anti-reflective (AR) region. In an embodiment, the second surface region 314 can include silicon nitride, boron nitride or titanium nitride. In an example, silicon nitride can be used as an anti-reflective coating. In an embodiment, the second surface region 316 can have a thickness greater than a thickness of the first surface region 314. In an embodiment, the second surface region 316 can have a thickness in the range of 50-100 nm. In one embodiment, the second surface region 316 can be substantially transparent.

In an embodiment, the silicon substrate 302 can be cleaned, polished, planarized and/or thinned or otherwise processed prior to the formation of the oxide regions 310 on the front side 304 of the solar cell 300. In an embodiment, the silicon substrate 302 can be single-crystalline or a multicrystalline silicon substrate. In an embodiment, the silicon substrate 302 can be an N-type or a P-type silicon substrate. In an embodiment, the N-type and P-type doped regions 332, 334 can be in the silicon substrate 302. In an embodiment, the N-type and P-type doped regions can be disposed on the substrate 302. In an example, the N-type and P-type doped regions 332, 334 can be doped polysilicon regions. In an embodiment, the doped polysilicon regions can be disposed on the silicon substrate 302. In one embodiment, a dielectric region (e.g., a tunnel oxide) can be disposed between the doped polysilicon regions and the silicon substrate 302.

In an embodiment, metal contact fingers 342, 344 can be disposed on the silicon substrate 302 to allow for pathways for electrical current conduction from the N-type and P-type doped regions 332, 334 to an external circuit. In an embodiment, a separation region 346 can be formed to separate metal contact fingers 342, 344 of different polarity (e.g., a positive and a negative contact finger 342, 344) from contacting. In some embodiments, the separation region 346 can include a trench region, where the trench region can be a partially etched region of the silicon substrate 302. In an example, the trench region can include a light receiving surface 311 on the back side 206 and/or, in some embodiments, the light receiving surface 311 can be texturized. In an embodiment, the metal contact fingers 342, 344 can instead be disposed on a front side 304 of a solar cell 300 (e.g., for a front-contact solar cell). In the same embodiment, the separation region 346 between metal contact fingers 342, 344 can be formed to allow for reduced shading, e.g., to maximize light collection, on a front surface of a front-contact solar cell.

In an embodiment, another oxide region 318 and silicon based region 320 can be disposed on the back side 306 of the silicon substrate 302, according to some embodiments. In an embodiment, the oxide region 318 on the back side 306 can include silicon oxide, among others. In an embodiment, the silicon based region 320 on the back side 306 can be an amorphous silicon, silicon nitride, or microcrystalline silicon, among others. In some embodiments, the oxide region and silicon based region 318, 320 can form an interfacial region 315 on the back side 306 of the solar cell 300. In an embodiment, the oxide regions 310, 318 and silicon based regions 312, 320 on the front and back sides 304, 306 can be formed in the same process (e.g., in the same thermal growth and/or deposition process). In some embodiments, the oxide region 318 and silicon based region 320 on the back side 306 of the silicon substrate 302 need not be formed. In an embodiment, the structure and/or the technique for forming of the interfacial region 315 is substantially similar to the structure and/or the technique for forming of the interfacial region 313 except the interfacial region 315 is located on the back side 204 of the solar cell 300. Accordingly, the description of the interfacial region 313 applies equally to the interfacial region 315 and will not be repeated here.

In an embodiment, surface regions 322, 324 can be disposed on the back side 306 of the silicon substrate 302. In an embodiment, the surface region 322 can include aluminum oxide. In an embodiment, the surface region 324 can include silicon nitride, boron nitride or titanium nitride. In an embodiment, the surface regions 314, 316 on the front side 204 and surface regions 322, 324 on the back side 206 can be formed in the same process (e.g., in the same deposition process). In some embodiments, the surface regions 322, 324 need not be formed. In an embodiment, the structure and/or the technique for forming of the surface regions 322, 324 are substantially similar to the structure and/or the technique for forming of the surface regions 314, 316 except the surface regions 322, 324 are located on the back side 304 of the solar cell 300. Accordingly, the description of the surface regions 314, 316 apply equally to surface regions 322, 324 and will not be repeated here.

Referring to the solar cells 200/300 of FIGS. 6 and 7, the combination of the interfacial region 213/313, first surface region 214/314 including aluminum oxide and the second surface region 216/316 can improve the overall solar cell efficiency, according to some embodiments. In an example, an interfacial region 213/313 including a silicon oxide and a silicon nitride region formed over the light receiving surface 209/309 of the silicon substrate 202/302, a first surface region 214/314 including aluminum oxide and a second surface region 216/316 including silicon nitride can improve the overall efficiency of the solar cell 200/300 in the range of 0.2-03% in comparison to a solar cell without a first surface region including aluminum oxide.

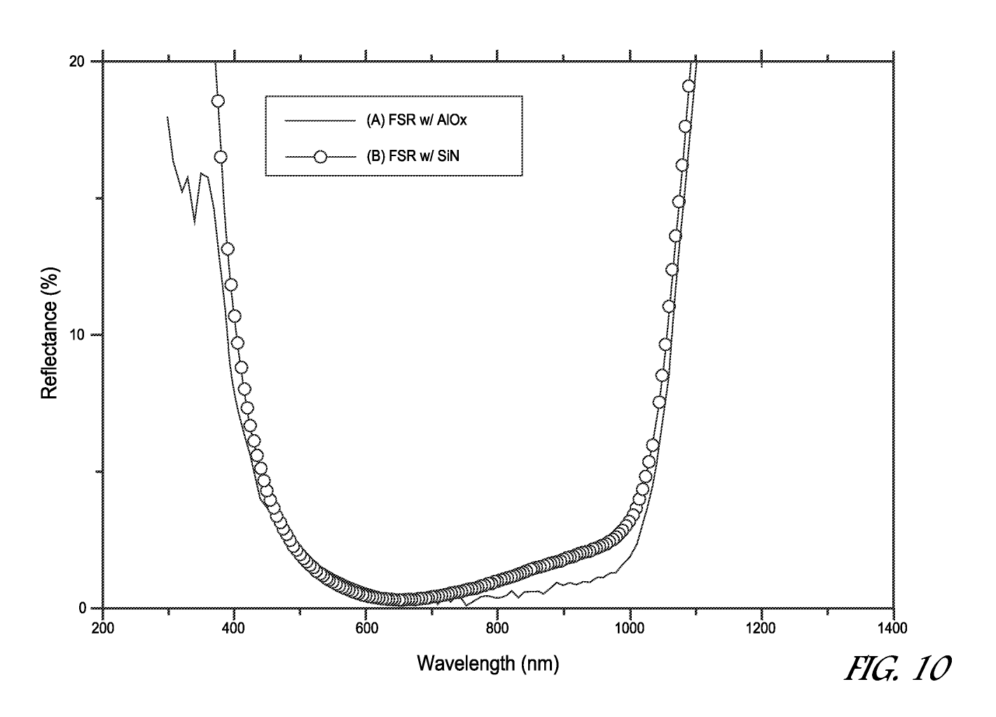

Referring to FIGS. 8 and 9, a graph of saturation current (Joe) for example solar cells (A) and (B) is shown. FIG. 8 specifically shows a comparison of Joe for a solar cell having a front surface region including aluminum oxide (AlOx) formed by a steam process (A) (e.g., a steam precursor process as discussed in FIG. 4) versus a solar cell solar cell having a front surface region including aluminum oxide (AlOx) formed with a non-steam process (B). As shown in FIG. 8, Joe is higher for the solar cell having a front surface region formed with the non-steam process (B). FIG. 9 specifically shows a comparison of Joe for the solar cell (A) versus the solar cell (B) as measured at different UV exposure times. In the example shown, the UV exposure time 1 was measured at time 0, exposure time 2 was measured after approximately 1 day of UV exposure, exposure time 3 was measured after approximately 2 days of UV exposure and exposure time 4 was measured after approximately 3 days of UV exposure. As shown in FIG. 9, Joe is increasingly higher for the solar cell having a front surface region formed with the non-steam process (B) as UV exposure time is lengthened indicating that the interface between the silicon substrate and oxide region (e.g., bulk silicon and a silicon oxide region) is increasingly depassivated as UV exposure time is lengthened. In comparison, for solar cell (A), the interface is better passivated and more resilient to UV radiation degradation.

With reference to FIG. 10, a graph of reflectance and wavelength for a solar cell formed with a front surface region (FSR) including an aluminum oxide (AlOx) (A) and a solar cell formed with a front surface region (FSR) including silicon nitride (SiN) (B). As shown in FIG. 10, the reflectance of the FSR with AlOx (A) is lower in the infrared range (e.g., from approximately 700 nm to 1000 nm) versus the FSR with SiN (B).

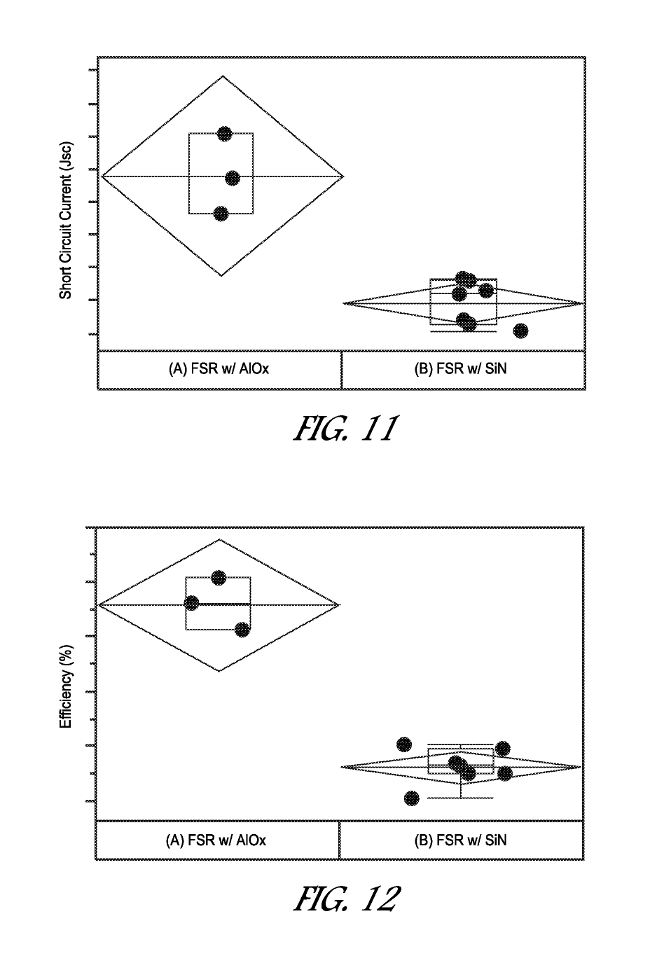

FIGS. 11 and 12 illustrate graphs of short circuit current (Jsc) and efficiency for example solar cells (A) and (B). FIGS. 11 and 12 specifically show a comparison of Jsc and efficiency in experiments performed on a solar cell having a front surface region (FSR) including aluminum oxide (AlOx) (A) versus a solar cell having a front surface region (FSR) including silicon nitride (SiN) (B). As shown in FIGS. 11 and 12, Jsc is higher with the AlOx FSR which results in substantially higher efficiency as compared to the SiN FSR (B).

Although specific embodiments have been described above, these embodiments are not intended to limit the scope of the present disclosure, even where only a single embodiment is described with respect to a particular feature. Examples of features provided in the disclosure are intended to be illustrative rather than restrictive unless stated otherwise. The above description is intended to cover such alternatives, modifications, and equivalents as would be apparent to a person skilled in the art having the benefit of this disclosure.

The scope of the present disclosure includes any feature or combination of features disclosed herein (either explicitly or implicitly), or any generalization thereof, whether or not it mitigates any or all of the problems addressed herein. Accordingly, new claims may be formulated during prosecution of this application (or an application claiming priority thereto) to any such combination of features. In particular, with reference to the appended claims, features from dependent claims may be combined with those of the independent claims and features from respective independent claims may be combined in any appropriate manner and not merely in the specific combinations enumerated in the appended claims.

What is claimed is:

1. A solar cell, the solar cell comprising:
a silicon substrate having a light receiving surface;
an interfacial region over the light receiving surface of the silicon substrate;
a first surface region comprising aluminum oxide over the interfacial region; and
a second surface region over the first surface region.

2. The solar cell of claim 1, wherein the first surface region comprising aluminum oxide has a thickness greater than a thickness of the second surface region.

3. The solar cell of claim 1, wherein the interfacial region comprises a silicon based region over an oxide region.

4. The solar cell of claim 1, wherein the interfacial region comprises amorphous silicon, silicon nitride, microcrystalline silicon, or silicon dioxide.

5. The solar cell of claim 1, wherein a thickness of the first surface region comprising aluminum oxide is in the range of 15-150 nm.

6. The solar cell of claim 1, wherein a thickness of the second surface region is in the range of 1-10 nm.

7. The solar cell of claim 1, wherein the second surface region comprises silicon nitride, boron nitride or titanium nitride.

8. A solar cell, the solar cell comprising:
a silicon substrate having a light receiving surface;
an interfacial region over the light receiving surface of the silicon substrate;
a first surface region comprising aluminum oxide formed over the interfacial region; and
a second surface region over the first surface region, wherein the second surface region has a thickness greater than a thickness of the first surface region.

9. The solar cell of claim 8, wherein the interfacial region comprises a silicon based region over an oxide region.

10. The solar cell of claim 8, wherein the interfacial region comprises amorphous silicon, silicon nitride, microcrystalline silicon, or silicon dioxide.

11. The solar cell of claim 8, wherein a thickness of the first surface region comprising aluminum oxide is in the range of 1-15 nm.

12. The solar cell of claim 8, wherein a thickness of the second surface region is in the range of 50-100 nm.

13. The solar cell of claim 8, wherein the second surface region comprises silicon nitride, boron nitride or titanium nitride.

14. A method of fabricating a solar cell, the method comprising:
forming an interfacial region over a light receiving surface of a silicon substrate;
forming a first surface region comprising aluminum oxide over the interfacial region; and
forming a second surface region over the first surface region.

15. The method of claim 14, wherein forming the first surface region comprising aluminum oxide comprises performing atomic layer deposition (ALD), plasma enhanced atomic layer deposition (PEALD), chemical vapor deposition (CVD), plasma enhanced chemical vapor deposition (PECVD), low-pressure chemical vapor deposition, molecular beam epitaxy (MBE) or sputtering.

16. The method of claim 14, wherein forming the first surface region comprising aluminum oxide comprises using a hydrogenated gas during an atomic layer deposition (ALD) process.

17. The method of claim 14, wherein forming the first surface region comprising aluminum oxide comprises depositing the aluminum oxide using steam precursors.

18. The method of claim 14, wherein forming the interfacial region comprises forming an oxide region over the light receiving surface of the silicon substrate and subsequently forming a silicon based region over the oxide region.

19. The method of claim 14, wherein forming the interfacial region comprises forming amorphous silicon, silicon nitride, or microcrystalline silicon or a silicon oxide over the light receiving surface of the silicon substrate.

20. The method of claim 14, further comprising, after forming the second surface region over the first surface region, performing an annealing process.
